(19) United States
(12) Patent Application Publication
(10) Pub. No.: US 2012/0119641 A1
(43) Pub. Date: May 17, 2012

(54) OUTPUT EFFICIENCY OF ORGANIC LIGHT EMITTING DEVICES

(76) Inventors: Yijian Shi, Mountain View, CA (US); Qianfei Xu, Mountain View, CA (US)

(21) Appl. No.: 13/319,323

(22) PCT Filed: May 13, 2010
(86) PCT No.: PCT/US10/34797

§ 371 Date: Jan. 13, 2012

Related U.S. Application Data
(60) Provisional application No. 61/178,412, filed on May 14, 2009.

(51) Int. Cl. H01J 1/63; H05K 13/00; H01J 9/00

(52) U.S. Cl. 313/503; 427/58; 427/66; 216/13; 29/592.1

(57) ABSTRACT

The invention provides methods and materials suitable for increasing the output efficiency of light emitting diodes (LEDs), particularly organic LEDs (OLEDs). In one embodiment, for example, there is described a method for providing a porous coating over an OLED stack. The porous coating reduces optical loss and improves light extraction efficiency from the OLED device.

### CROSS REFERENCE TO RELATED APPLICATIONS

This application claims priority under 35 U.S.C. §119 to U.S. Provisional Application Ser. No. 61/178,412, filed May 14, 2009, the content of which is incorporated herein by reference in its entirety.

### TECHNICAL FIELD

The present invention is directed to organic light emitting devices having improved output efficiency, as well as the materials and methods suitable for their production. The invention finds utility, for example, in the field of electronic devices.

### BACKGROUND

In some versions of traditional layered Light Emitting Diode (LED) and Organic LED (OLED) devices, a transparent substrate serves the dual purpose of supporting the LED component layers (the “LED stack”) and providing a protective barrier between the LED stack and the environment. Light emitted by the LED passes through the transparent substrate, and in doing so, traverses the interface between the substrate material and the environment. Typically, the environment is air, but may also be an inert gas or vacuum. This environment/substrate interface is typically the last interface that is traversed by the exiting photons. Depending on the refractive indices of the substrate material and the environment, as well as other factors such as the device geometry, a significant portion of photons encountering the environment/substrate interface do so at an angle of incidence great enough to be internally reflected. Accordingly, for many LEDs there is a significant optical loss due to total reflection from the environment/substrate interface of the device front panel.

A similar phenomenon occurs for LED devices having a transparent electrode as the outermost device layer (i.e., the layer that forms an interface with the environment), or a transparent electrode coated with a transparent protective coating. Again, when photons exiting the device encounter the barrier between the environment and the electrode or protective coating, a significant amount of optical loss occurs.

Reducing the optical loss that occurs at the barrier between the outermost device layer and the environment would be desirable because it would improve device efficiency and improve device lifetime.

Various engineering approaches, such as using photonic crystals or arrays of microlenses, have been proposed or investigated to reduce the optical losses of an LED. Since these approaches generally require the use of lithographic processes, they significantly increase production cost. Other drawbacks of these approaches include a tendency to increase the complexity of production and to decrease device stability.

There remains a need in the art to overcome the abovementioned drawbacks, as well as generally to develop new methods and materials for increasing the efficiency of LEDs. Ideal methods would utilize materials that are readily available or easily prepared, provide significant enhancements in device output (efficiency and/or total output), minimize the number of process steps, and/or provide highly reproducible results.

### SUMMARY OF THE INVENTION

The present invention is directed to providing methods and materials for improving the output and output efficiency of LED devices, as well as LED devices having improved output and output efficiency.

In one aspect, there is provided a light emitting diode (LED) device comprising a transparent substrate layer having first and second sides, a first electrode layer contacting the first side of the substrate layer, an electroluminescent layer contacting the first electrode layer, a second electrode layer contacting the electroluminescent layer and a porous layer contacting the second side of the substrate.

In another aspect, there is provided a LED device comprising a substrate layer, a first electrode layer contacting the substrate layer, an electroluminescent layer contacting the first electrode layer, and a second electrode layer. A first side of the second electrode layer contacts the electroluminescent layer, and the second electrode layer is transparent. A porous layer contacts a second side of the second electrode layer.

In another aspect, there is provided a LED device comprising a substrate layer having first and second sides, a first electrode layer contacting the first side of the substrate layer, an electroluminescent layer contacting the first electrode layer, a second electrode layer contacting the electroluminescent layer, and an optional encapsulation layer contacting the second electrode layer. Either the second side of the substrate layer or the optional encapsulation layer comprises surface roughness prepared by mechanically ablating the surface.

In another aspect, there is provided a method for increasing the efficiency of a LED. The method comprises applying to the LED a transparent pre-porous layer comprising a cross-linkable matrix material and a porogen, and forming a transparent porous layer by removing all or a portion of the porogen and cross-linking the matrix material.

In another aspect, there is provided a method for increasing the efficiency of an LED. The LED has an outermost layer that forms an interface between the LED and the environment. The method comprises contacting the transparent outermost layer with a porous transparent layer such that the porous transparent layer affixes to the outermost layer.

Other aspects of the invention will be apparent from the description that follows, including the claims and examples.

### BRIEF DESCRIPTION OF THE DRAWINGS

FIG. 1 provides a schematic representation of an embodiment of a porous layer overlaying an OLED according to the invention. The porous layer contains microcavities that extend from the external surface of the porous layer into the interior of the porous layer (in the figure, the microcavities extend into the porous layer by approximately 25%-35% of the thickness of the porous layer, although the figure is not to scale and, as described herein, the microcavities may extend into the porous layer much less than shown in FIG. 1). Also illustrated in the figure are light rays emitted by the OLED stack having various trajectories.

FIG. 2 provides a schematic representation of an embodiment of the preparation of a porous layer according to the invention. A pre-porous layer, having pores filled with a porogen material, is shown in panel (a). A porous layer, having pores open to the environment, is shown in panel (b).

FIG. 3 provides data showing external quantum efficiency (EQE) as a function of applied voltage for a device treated by sandblasting the outer surface of the glass substrate.

FIG. 4 provides data showing the external quantum efficiency (EQE) as a function of brightness for a device before and after apply a coating using the methods of the invention.

### DETAILED DESCRIPTION OF THE DISCLOSURE

Before describing the present invention in detail, it is to be understood that unless otherwise indicated, this invention is not limited to any particular embodiment described herein, as such may vary. It is also to be understood that the terminology used herein is for the purpose of describing particular embodiments only, and is not intended to be limiting. The definitions provided herein are not meant to be mutually exclusive. For example, it will be appreciated that some chemical groups may fit into more than one definition.

The term “alkyl” as used herein refers to a branched or unbranched saturated hydrocarbon group typically although not necessarily containing 1 to about 24 carbon atoms, such as methyl, ethyl, n-propyl, isopropyl, n-butyl, isobutyl, t-butyl, octyl, decyl, and the like, as well as cycloalkyl groups such as cyclopentyl, cyclohexyl and the like. Generally, although again not necessarily, alkyl groups herein may contain 1 to about 18 carbon atoms, and such groups may contain 1 to about 12 carbon atoms. The term “lower alkyl” intends an alkyl group of 1 to 6 carbon atoms. “Substituted alkyl” refers to alkyl substituted with one or more substituent groups, and the terms “heteroatom-containing alkyl” and “heteroalkyl” refer to an alkyl substituent in which at least one carbon atom is replaced with a heteroatom, as described in further detail infra. If not otherwise indicated, the terms “alkyl” and “lower alkyl” include linear, branched, cyclic, unsubstituted, substituted, and/or heteroatom-containing alkyl or lower alkyl, respectively.

The term “alkenyl” as used herein refers to a linear, branched or cyclic hydrocarbon group of 2 to about 24 carbon atoms containing at least one double bond, such as ethenyl, n-propenyl, isopropenyl, n-butenyl, isobutenyl, octenyl, decenyl, tetradecenyl, hexadecenyl, eicosenyl, tetracosenyl, and the like. Generally, although again not necessarily, alkenyl groups herein may contain 2 to about 18 carbon atoms, and for example may contain 2 to 12 carbon atoms. The term “lower alkenyl” intends an alkenyl group of 2 to 6 carbon atoms. The term “substituted alkenyl” refers to alkenyl substituted with one or more substituent groups, and the terms “heteroatom-containing alkenyl” and “heteroalkenyl” refer to alkenyl in which at least one carbon atom is replaced with a heteroatom. If not otherwise indicated, the terms “alkenyl” and “lower alkenyl” include linear, branched, cyclic, unsubstituted, substituted, and/or heteroatom-containing alkenyl and lower alkenyl, respectively.

The term “alkynyl” as used herein refers to a linear or branched hydrocarbon group of 2 to 24 carbon atoms containing at least one triple bond, such as ethynyl, n-propynyl, and the like. Generally, although again not necessarily, alkynyl groups herein may contain 2 to about 18 carbon atoms, and such groups may further contain 2 to 12 carbon atoms. The term “lower alkynyl” intends an alkynyl group of 2 to 6 carbon atoms. The term “substituted alkynyl” refers to alkynyl substituted with one or more substituent groups, and the terms “heteroatom-containing alkynyl” and “heteroalkynyl” refer to alkynyl in which at least one carbon atom is replaced with a heteroatom. If not otherwise indicated, the terms “alkynyl” and “lower alkynyl” include linear, branched, unsubstituted, substituted, and/or heteroatom-containing alkynyl and lower alkynyl, respectively.

If not otherwise indicated, the term “unsaturated alkyl” includes alkenyl and alkynyl, as well as combinations thereof.

The term “alkoxy” as used herein intends an alkyl group bound through a single, terminal ether linkage; that is, an “alkoxy” group may be represented as —O-alkyl where alkyl is as defined above. A “lower alkoxy” group intends an alkoxy group containing 1 to 6 carbon atoms, and includes, for example, methoxy, ethoxy, n-propoxy, isopropoxy, t-butyloxy, etc. Substituents identified as “C₁-C₆ alkoxy” or “lower alkoxy” herein may, for example, may contain 1 to 3 carbon atoms, and as a further example, such substituents may contain 1 or 2 carbon atoms (i.e., methoxy and ethoxy).

The term “aryl” as used herein, and unless otherwise specified, refers to an aromatic substituent generally, although not necessarily, containing 5 to 30 carbon atoms and containing a single aromatic ring or multiple aromatic rings (such as 1 to 3 rings) that are fused together, directly linked, or indirectly linked (such that the different aromatic rings are bound to a common group such as a methylene or ethylene moiety). Aryl groups may, for example, contain 5 to 20 carbon atoms, and as a further example, aryl groups may contain 5 to 12 carbon atoms. For example, aryl groups may contain one aromatic ring or two fused or linked aromatic rings, e.g., phenyl, naphthyl, biphenyl, diphenylether, diphenylamine, benzophenone, and the like. “Substituted aryl” refers to an aryl moiety substituted with one or more substituent groups, and the terms “heteroatom-containing aryl” and “heteroaryl” refer to an aryl substituent, in which at least one carbon atom is replaced with a heteroatom, as will be described in further detail infra. If not otherwise indicated, the term “aryl” includes unsubstituted, substituted, and/or heteroatom-containing aryl substituents.

The term “aralkyl” refers to an alkyl group with an aryl substituent, and the term “alkaryl” refers to an aryl group with an alkyl substituent, wherein “alkyl” and “aryl” are as defined above. In general, aralkyl and alkaryl groups herein contain 6 to 30 carbon atoms. Aralkyl and alkaryl groups may, for example, contain 6 to 20 carbon atoms, and as a further example, such groups may contain 6 to 12 carbon atoms.

The term “olefinic group” intends a mono-unsaturated or di-unsaturated hydrocarbon group of 2 to 12 carbon atoms. Preferred olefinic groups within this class are sometimes herein designated as “lower olefinic groups,” intending a hydrocarbon moiety of 2 to 6 carbon atoms containing a single terminal double bond. The latter moieties may also be termed “lower alkenyl.”

The term “alkylene” as used herein refers to a difunctional saturated branched or unbranched hydrocarbon chain containing from 1 to 24 carbon atoms. “Lower alkylene” refers to alkylene linkages containing from 1 to 6 carbon atoms, and includes, for example, methylene (—CH₂—), ethylene (—CH₂CH₂—), propylene (—CH₂CH₂CH₂—), 2-methylpropylene (—CH₂—CH(CH₃)—CH₂—), hexylene (—(CH₂)₆—) and the like.

The term “amino” is used herein to refer to the group —NZ¹Z² wherein Z¹ and Z² are hydrogen or nonhydrogen substituents, with nonhydrogen substituents including, for example, alkyl, aryl, alkenyl, aralkyl, and substituted and/or heteroatom-containing variants thereof.

The term “heteroatom-containing” as in a “heteroatom-containing alkyl group” (also termed a “heteroalkyl” group) or a “heteroatom-containing aryl group” (also termed a “heteroaryl” group) refers to a molecule, linkage or substituent in which one or more carbon atoms are replaced with an atom other than carbon, e.g., nitrogen, oxygen, sulfur, phosphorus or silicon, typically nitrogen, oxygen or sulfur. Similarly, the term “heteroalkyl” refers to an alkyl substituent that is heteroatom-containing, the term “heterocyclic” refers to a cyclic substituent that is heteroatom-containing, the terms “heteroaryl” and heteroaromatic” respectively refer to “aryl” and “aromatic” substituents that are heteroatom-containing, and the like. Examples of heteroalkyl groups include alkoxyaryl, alkylsulfanyl-substituted alkyl, N-alkylated amino alkyl, and the like. Examples of heteroaryl substituents include pyrrolyl, pyrrolidinyl, pyridinyl, quinolinyl, indolyl, furyl, pyrimidinyl, imidazolyl, 1,2,4-triazolyl, tetrazolyl, etc., and examples of heteroatom-containing alicyclic groups are pyrrolidino, morpholino, piperazino, piperidino, tetrahydrofuranyl, etc.

“Hydrocarbyl” refers to univalent hydrocarbyl radicals containing 1 to about 30 carbon atoms, including 1 to about 24 carbon atoms, further including 1 to about 18 carbon atoms, and further including about 1 to 12 carbon atoms, including linear, branched, cyclic, saturated and unsaturated species, such as alkyl groups, alkenyl groups, aryl groups, and the like. “Substituted hydrocarbyl” refers to hydrocarbyl substituted with one or more substituent groups, and the term “heteroatom-containing hydrocarbyl” refers to hydrocarbyl in which at least one carbon atom is replaced with a heteroatom. Unless otherwise indicated, the term “hydrocarbyl” is to be interpreted as including unsubstituted, substituted, heteroatom-containing, and substituted heteroatom-containing hydrocarbyl moieties.

“Halo” or “halogen” refers to fluoro, chloro, bromo or iodo, and usually relates to halo substitution for a hydrogen atom in an organic compound. Of the halos, chloro and fluoro are generally preferred.

By “substituted” as in “substituted hydrocarbyl,” “substituted alkyl,” “substituted aryl,” and the like, as alluded to in some of the aforementioned definitions, is meant that in the hydrocarbyl, alkyl, aryl, or other moiety, at least one hydrogen atom bound to a carbon (or other) atom is replaced with one or more non-hydrogen substituents. Examples of such substituents include, without limitation: functional groups such as halo, hydroxyl, sulfhydryl, C₁-C₂₄ alkoxy, C₂-C₂₄ alkenyloxy, C₂-C₂₄ alkynyloxy, C₅-C₂₀ aryloxy, acyl (including C₂-C₂₄ alkylcarbonyl (—CO-alkyl) and C₆-C₂₀ arylcarbonyl (—CO-aryl)), acyloxy (—O-acyl), C₂-C₂₄ alkoxycarbonyl (—(CO)—O-alkyl), C₆-C₂₀ aryloxycarbonyl (—(CO)—O-aryl), halocarbonyl (—CO)—X where X is halo), C₂-C₂₄ alkylcarbonato (—O—(CO)—O-alkyl), C₆-C₂₀ arylcarbonato (—O—(CO)—O—aryl), carboxy (—COOH), carboxylato (—COO⁻), carbamoyl (—(CO)—NH₂), mono-substituted C₁-C₂₄ alkylcarbamoyl (—(CO)—NH(C₁-C₂₄ alkyl)), di-substituted alkylcarbamoyl (—(CO)—N(C₁-C₂₄ alkyl)₂), mono-substituted arylcarbamoyl (—(CO)—NH-aryl), thiocarbamoyl (—(CS)—NH₂), carbamido (—NH—(CO)—NH₂), cyano (—C≡N), isocyano (—N⁺≡C⁻), cyanato (—O—C≡N), isocyanato (—O—N⁺≡C⁻), isothiocyanato (—S—C≡N), azido (—N═N⁺═N⁻), formyl (—(CO)—H), thioformyl (—(CS)—H), amino (—NH₂), mono- and di-(C₁-C₂₄ alkyl)-substituted amino, mono- and di-(C₅-C₂₀ aryl)-substituted amino, C₂-C₂₄ alkylamido (—NH—(CO)-alkyl), C₅-C₂₀ arylamido (—NH—(CO)-aryl), imino (—CR═NH where R=hydrogen, C₁-C₂₄ alkyl, C₅-C₂₀ aryl, C₆-C₂₀ alkaryl, C₆-C₂₀ aralkyl, etc.), alkylimino (—CR═N(alkyl), where R=hydrogen, alkyl, aryl, alkaryl, etc.), arylimino (—CR═N(aryl), where R=hydrogen, alkyl, aryl, alkaryl, etc.), nitro (—NO₂), nitroso (—NO), sulfo (—O₂—OH), sulfonato (—SO₂—O⁻), C₁-C₂₄ alkylsulfanyl (—S-alkyl; also termed “alkylthio”), arylsulfanyl (—S-aryl; also termed “arylthio”), C₁-C₂₄ alkylsulfinyl (—(SO)-alkyl), C₅-C₂₀ arylsulfinyl (—(SO)-aryl), C₁-C₂₄ alkylsulfonyl (—SO₂-alkyl), C₅-C₂₀ arylsulfonyl (—SO₂-aryl), phosphono (—P(O)(OH)₂), phosphonato (—P(O)(O⁻)₂), phosphinato (—P(O)(O⁻)), phospho (—PO₂), and phosphino (—PH₂), mono- and di-(C₁-C₂₄ alkyl)-substituted phosphino, mono- and di-(C₅-C₂₀ aryl)-substituted phosphino; and the hydrocarbyl moieties C₁-C₂₄ alkyl (including C₁-C₁₈ alkyl, further including C₁-C₁₂ alkyl, and further including C₁-C₆ alkyl), C₂-C₂₄ alkenyl (including C₂-C₁₈ alkenyl, further including C₂-C₁₂ alkenyl, and further including C₂-C₆ alkenyl), C₂-C₂₄ alkynyl (including C₂-C₁₈ alkynyl, further including C₂-C₁₂ alkynyl, and further including C₂-C₆ alkynyl), C₅-C₃₀ aryl (including C₅-C₂₀ aryl, and further including C₅-C₁₂ aryl), and C₆-C₃₀ aralkyl (including C₆-C₂₀ aralkyl, and further including C₆-C₁₂ aralkyl). In addition, the aforementioned functional groups may, if a particular group permits, be further substituted with one or more additional functional groups or with one or more hydrocarbyl moieties such as those specifically enumerated above. Analogously, the above-mentioned hydrocarbyl moieties may be further substituted with one or more functional groups or additional hydrocarbyl moieties such as those specifically enumerated.

When the term “substituted” appears prior to a list of possible substituted groups, it is intended that the term apply to every member of that group. For example, the phrase “substituted alkyl and aryl” is to be interpreted as “substituted alkyl and substituted aryl.”

Unless otherwise specified, reference to an atom is meant to include isotopes of that atom. For example, reference to H is meant to include ¹H, ²H (i.e., D) and ³H (i.e., T), and reference to C is meant to include ¹²C and all isotopes of carbon (such as ¹³C).

As used herein, the term “transparent” refers to a material that is permeable to electromagnetic radiation. In the specific context of a transparent coating employed in an LED, the term refers to a material that is permeable to the wavelengths of electromagnetic radiation that are emitted by the LED. Unless stated otherwise, the term includes materials that are completely permeable as well as materials that are semi-permeable.

In some embodiments, then, the invention provides methods and materials suitable for enhancing one or more measures of performance of an LED. In preferred embodiments, the LED is an organic LED (OLED), although the invention is not limited as such. Throughout this disclosure, references are made to OLEDs, although it will be appreciated that such references specify OLEDs merely as exemplary, and that the invention is equally applicable to LEDs generally.

The measures of performance that may be enhanced include, without limitation, external quantum efficiency (i.e., number of photons that escape the device/number of electrons flowing through the device), intensity (per unit area and/or total), and luminous efficacy (lumen per watt).

In some embodiments, the invention provides methods for creating an external surface for an LED. As used herein, the term “external surface” refers to the surface that forms the outermost barrier of the LED—i.e., the interface between the LED and the environment. It will be appreciated that the environment may consist of any of a variety of substances, including (but not limited to) air, inert gases such as argon or nitrogen, reactive gases such as oxygen or hydrogen, fluids such as water or organic solvents, and any combination. Typically, the environment consists of liquids or gases. In some instances, the environment will consist of a gas or mixture of gases at reduced pressure, and in some instances, the environment will consist of a vacuum (i.e., the absence or near absence of material).

Configurations of OLEDs appropriate for the invention will vary. Typical OLED stacks comprise the following components: an electron injection electrode layer, an electroluminescent layer, a hole injection electrode layer, and a substrate. Although it is possible for one of the electrode layers to function as a substrate, and such an embodiment is within the scope of the present invention, typical OLEDs comprise a separate substrate layer. Additional components may include dielectric layers and encapsulating layers. Furthermore, the electrodes may each comprise one or more material layers. For example, a combination of two materials may form an anode/hole injection electrode, and a combination of two materials may for a cathode/electron injection electrode. OLEDs may be configured such that photons emitted by the electroluminescent layer travel through the substrate (in which case the substrate is transparent) or through one of the electrodes (in which case that electrode is transparent). OLEDs comprising cavities, where electroluminescent material is disposed within the cavities and emission occurs at least partially from within the cavities (“Cavity OLED” or “COLED” devices), are also within the scope of the invention.

OLED geometries suitable for this invention include, for example, those described in the following patents and patent application publications, the relevant contents of which are incorporated herein by reference: U.S. Pat. Nos. 6,593,687, 6,723,828, 6,800,722, and 7,098,297; US Patent Application Publication No. US 2008/0248240; and PCT Publication Nos. WO 2009/093996 and WO 2009/025870.

The OLEDs of the invention comprise a transparent outermost layer, through which photons emitted by the device pass before exiting the device and entering the environment. In preferred embodiments, the transparent outermost layer is the substrate. In other embodiments, the transparent outermost layer is a transparent electrode layer, such as a transparent hole injection layer or a transparent electron injection layer. In still further embodiments, the transparent outermost layer is an encapsulation layer (i.e., a protective layer covering the OLED stack). In this disclosure, the “external surface” of the transparent outermost layer refers to the surface that interfaces with the environment, whereas the “internal surface” of the transparent outermost layer refers to the surface that interfaces with the underlying layer (e.g., an electrode or another component from the OLED stack).

In some embodiments of the invention, the transparent outermost layer of an OLED is modified to include surface roughness. In other embodiments of the invention, the transparent outermost layer of an OLED retains a (relatively) smooth surface, and an additional layer is applied to the surface. It will be appreciated that, in such embodiments, the additional layer becomes the “outermost” layer of the device.

In embodiments where the transparent outermost layer of the OLED is modified to include surface roughness, such modification may be accomplished by any appropriate means. For example, the surface may be subjected to a fine stream of sand particles traveling at high velocity (i.e., sand blasted). Impact of the sand particles with the surface creates indentations and other surface features that increase the roughness of the surface. The diameter of the sand particles, the momentum with which they impact the surface, and the quantity of particles impacting the surface are factors that can be varied to achieve the desired level of surface roughness. Materials other than sand may be used in this technique. In another example, the surface may be subjected to mechanical grinding or polishing by a material having a roughened surface (e.g., sandpaper or the like).

In other embodiments, the transparent outermost layer of an OLED is not modified. Instead, an additional layer (also called a porous layer) is applied over the transparent outermost layer of the OLED. The porous layer becomes the new outermost layer of the device, since it overlays the layer that was previously the outermost layer, and forms the interface between the device and the environment. Photons exiting the OLED travel through the porous layer immediately before entering the environment. In this disclosure, once a porous layer has been deposited over the transparent outermost layer, the latter layer will be referred to as the “penultimate layer.” Furthermore, in this disclosure, the “external surface” of the porous layer refers to the surface that interfaces with the environment, whereas the “internal surface” of the porous layer refers to the surface that interfaces with the penultimate layer.

The porous layer comprises a matrix material and a plurality of pores (also referred to as “voids”). Although some such pores may be entirely encapsulated within the porous layer (e.g., closed cell pores that do not breach the external surface of the porous layer), typically a plurality of the pores are located at the external surface of the porous layer. Pores that intersect the external surface of the porous layer are also referred to herein as “microcavities.” Such microcavities extend into the porous layer from the external surface. The walls of the microcavities are continuous with the external surface of the porous layer, but are disposed at various angles to the external surface of the porous layer. When photons traveling through the porous layer approach the external surface of the porous layer, a portion of the photons encounter the walls of the microcavities, and exit the device via the walls. Although the walls of the microcavities are continuous with the external surface of the porous layer, and are therefore part of the external surface (i.e., the walls form an interface with the environment, as does the external surface of the porous layer), references made herein to the “external surface of the porous layer” are typically not intended to include the microcavity walls. However, it will be clear from the context when such references are intended to include the microcavity walls.

The microcavities are not limited to any particular shape. In some embodiments, the microcavities are created by removal of spherical porogen particles, and are therefore also spherical (it will be appreciated that the term “spherical” is not limited to exact spheres, but also includes spheres having abnormalities, egg-shaped particles, and other misshapen sphere-like shapes). In some embodiments, the microcavities are, in cross-section, rectangular, square, trapezoidal, or triangular. In some embodiments, the microcavities have no regular shape (i.e., are irregular).

In traditional devices lacking microcavities or surface roughness (i.e., devices having a smooth external surface of the outermost layer), photons may be emitted from the OLED stack at trajectories such that, when the photons encounter the external surface of the outermost layer, the photons are reflected back into the outermost layer rather than passing through the external surface and exiting the device into the environment. This phenomenon, called total internal reflection, occurs when the angle of incidence of the photon on the external surface of the outermost layer is greater than a threshold value. The threshold value depends upon the relative indices of refraction of the outermost layer and of the environment. Total internal reflection reduces the number of photons that exit the device, thereby decreasing the EQE and total brightness of the device.

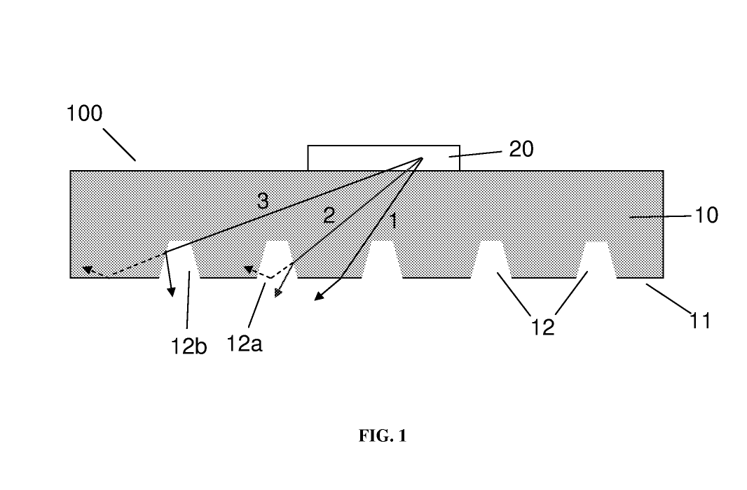

Because the walls of the microcavities intersect the external surface of the porous layer at various angles, a photon exiting the device through a microcavity wall does so at an angle that is typically different from the angle that a photon having the same trajectory would encounter in the absence of the microcavity. To illustrate this phenomenon, consider devices A and B, wherein device A has a porous layer comprising microcavities, device B lacks a porous layer and has a smooth external surface of the outermost layer, and the devices are otherwise identical. Photon P1 in device A, having a certain trajectory, will exit the device through a microcavity at an angle A1. Photon P2 in device B, having the same trajectory as photon P1, will exit the device through the external surface of the outermost layer at an angle B1. Even when angle B1 is such that total internal reflection occurs for photon P2, angle A1 may be such that photon A1 is able to exit the device via refraction, reflection, or a combination thereof. Via this phenomenon, the microcavities of the porous layer (or, alternatively, the surface roughness of the outermost layer for devices not containing a porous layer) reduce the number of photons that are reflected back into the device. This phenomenon is further illustrated in FIG. 1, which is described in more detail below.

The porous layer may be applied as a pre-porous layer. In these embodiments, the pre-porous layer comprises a matrix material and a porogen. After deposition of the pre-porous layer, the porogen is removed, leaving a porous layer as the outermost layer. Methods for removal of the porogen vary depending on the type of porogen used, and are described in more detail below. The matrix material is, in some embodiments, a cross-linkable material that is cross-linked either before or, more preferably, after removal of the porogen.

### Materials

Materials that are suitable for substrates in the methods of the invention are transparent or semi-transparent and are compatible with the OLED devices. Polymers and amorphous or semi-crystalline ceramics are preferred materials. Examples of inorganic materials include silicon dioxide (i.e., silica glass), various silicon-based glasses such as soda-lime glass and borosilicate glass, aluminum oxide, zirconium oxide, sodium chloride, diamond, and/or the like. Examples of transparent or semi-transparent polymeric materials include polyethylenenaphthalate, polycarbonate, polyethylene, polypropylene, polyester, polyimide, polyamides, polyacrylates, polymethacryates, and copolymers and mixtures thereof. The substrate may be rigid or flexible and may be of any suitable shape and configuration.

In embodiments where a non-transparent substrate is used, one of the electrodes of the OLED will be made from a transparent electrode material such that photons are emitted from the device through the transparent electrode. Examples of transparent electrode materials include Indium Tin Oxide (ITO), etc. In some embodiments, the electrode may be made of a layer of material that is sufficiently thin to impart transparency to the material, whereas the material is normally non-transparent in bulk form. An example is an electrode made of a very thin layer of aluminum metal.

As mentioned previously, the porous layer comprises a matrix material. In some embodiments, the matrix material (also referred to herein as a preceramic material) is a non-conductive material that is crosslinked or capable of forming a crosslinked network. When the porous layer is first deposited as a pre-porous layer, the pre-porous layer also comprises a matrix material in either crosslinked or cross-linkable form.

In some embodiments, the matrix material is a silicon-containing material that may be organic or completely inorganic. As an example, the matrix material may have the structure of the preceramic materials described in U.S. Pat. No. 5,246,738 to Blum, issued Sep. 21, 1993 (“Hydridosiloxanes as Precursors to Ceramic Products”), and in co-pending U.S. patent application Ser. No. 12/330,319, filed Dec. 8, 2008, and may be synthesized by the methods disclosed therein. The disclosure of these documents pertaining to such materials and methods is hereby incorporated by reference.

For example, the matrix material may comprise repeat units having the structure of formula (I):

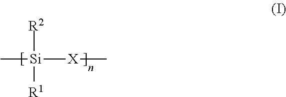

wherein R¹ and R² are independently selected from H, OH, C₁-C₃₀ hydrocarbyl, organometallic, halocarbyl, and organosilyl, each of which may be optionally substituted and optionally heteroatom containing, and wherein X is selected from —O—, and —NR³—, wherein R³ is hydrocarbyl. For example, each R¹ and R² may be H, OH, or hydrocarbyl. In preferred embodiments, R¹ and R² are selected from H, OH, C₁-C₂₀ alkyl, C₂-C₂₀ alkenyl, C₂-C₂₀ alkynyl, C₁-C₂₀ alkoxy, C₅-C₂₀ aryl, C₅⁻C₂₀ aryloxy, C₆-C₂₀ aralkyl, and C₆-C₂₀ alkaryl. In further preferred embodiments, R¹ and R² are selected from substituted or unsubstituted C₁-C₂₀ alkyl, substitute or unsubstituted heteroatom-containing C₁-C₂₀ alkyl, substituted or unsubstituted C₂-C₂₀ alkenyl, substitute or unsubstituted heteroatom-containing C₂-C₂₀ alkenyl, substituted or unsubstituted C₂-C₂₀ alkynyl, substitute or unsubstituted heteroatom-containing C₂-C₂₀ alkynyl, substituted or unsubstituted C₅-C₂₀ aryl, substitute or unsubstituted C₅-C₂₀ heteroaryl, substituted or unsubstituted C₅-C₂₀ aralkyl, substitute or unsubstituted heteroatom-containing C₅-C₂₀ aralkyl, substituted or unsubstituted C₆-C₂₀ alkaryl, and substitute or unsubstituted heteroatom-containing C₅-C₂₀ alkaryl. In some embodiments, R² is OH and R¹ is selected from alkyl, alkenyl, alkynyl, alkoxy, aryl, aryloxy, aralkyl, and alkaryl, any of which may be heteroatom containing, and any of which may be unsubstituted or substituted with one or more groups selected from halo, hydroxyl, alkyl, and aryl. In some embodiments, R¹ is lower alkyl, such as methyl or ethyl, and R² is H, OH, or C₁-C₂₀ alkoxy. In some preferred embodiments, X is —O—, such that the bonding material is a siloxane or polysiloxane material.

Furthermore in formula (I), n is an integer that is greater than or equal to 1. Accordingly, monomers, dimers, trimers, and higher-order materials such as oligomers and polymers are suitable. It will be appreciated that the matrix material may comprise a mixture of different compounds, each comprising repeat units having the structure of formula (I) but having various values of n.

For example, the matrix material may comprise repeat units having the formula [R¹Si(OH)O], [R¹Si(OR^{2a})O], and/or [R¹Si(H)O], wherein R¹ is as defined above and R^{2a} is selected from hydrocarbyl and organosilyl.

The matrix material is either crosslinked or cross-linkable via a curing reaction. Curing can be carried out using any method that is effective in crosslinking the bonding material. For example, application of heat and/or UV radiation for a predetermined period of time is an effective method of curing bonding materials that crosslink at elevated temperature and/or exposure to radiation. Alternatively or in addition, a crosslinking catalyst such as an organic amine or another organic base may be used to crosslink the bonding material. It will be appreciated that, in some cases, there is no need to induce the curing reaction (e.g., by applying heat), as such reaction will occur spontaneously. In preferred embodiments, any byproducts that result from the curing reaction are small molecules (e.g., water, methanol, and the like) that are conveniently removed by solvent washes.

In some embodiments, after curing, the matrix material comprises crosslinked units having the structure —[Si(R²)(X)_{1.5}]—, wherein: R² is selected from H, hydroxyl, fluorocarbyl, and hydrocarbyl; X is selected from —O— and —NR³—; and R³ is selected from alkyl and aryl. For example, X is —O— and R² is selected from alkyl, alkenyl, alkynyl, alkoxy, aryl, aryloxy, aralkyl, and alkaryl, any of which may be heteroatom containing, and any of which may be unsubstituted or substituted with one or more groups selected from halo, hydroxyl, alkyl, and aryl.

The matrix materials described above may be prepared, for example, using a dehydrocoupling reaction and/or hydrosilylation reaction as described in U.S. application Ser. No. 12/330,319. For example, the matrix material may be prepared by the reaction of polyhydridomethylsiloxane (PHMS) with water and/or an alcohol in the presence of a transition metal catalyst such as Ru₃(CO)₁₂, H₂PtCl₆, or the like. The matrix material, once prepared, can be purified of the transition metal catalyst using, for example, silica gel or charcoal column as is typical in the art.

In addition or in the alternative to the materials described above, the matrix material may comprise other crosslinked or cross-linkable materials. In some embodiments, the matrix material is a crosslinked or cross-linkable polymer such as polyester, polyimide, polyamides, polyacrylates, polymethacryates, epoxies (including thermally curable and UV curable epoxies) and copolymers and mixtures thereof.

In some embodiments, the matrix material comprises a polymer that is not crosslinked or crosslinkable. For example, the matrix material may be polycarbonate, polyacrylic, ultrahigh molecular weight polyethylene (UHMWPE), or a material with similar properties. Particularly in embodiments where a porous layer is not used (i.e., where surface roughness is obtained via mechanical methods such as sandblasting), a non-crosslinked polymer material such as polycarbonate or polyethylene may be used. Alternatively, crosslinked polymers such as those described above may be used.

The porous layer may be formed by removing a porogen from a pre-porous layer. Accordingly, a pre-porous layer comprises a matrix material (as described above, either a crosslinked or a cross-linkable material) and a porogen. The porogen is a particulate material that capable of being degraded or otherwise removed from the pre-porous layer.

Suitable materials for the porogen include, for example, metals and metal oxides. Examples of suitable metal and metal oxide materials for the porogen particles include aluminum, titanium, iron, chromium, magnesium, cobalt, nickel, copper, zinc, silicon etc., as well as oxides of such metals (such as aluminum oxide, titanium dioxide, etc.). Compounds suitable for reacting with each of these materials are known in the art, and include acids such as hydrochloric acid, hydrofluoric acid, sulfuric acid, phosphoric acid, and nitric acid, as well as bases such as sodium hydroxide. For example, aluminum porogen particles may be removed from the pre-porous layer via reaction (dissolution) with hydrochloric acid.

Other materials that are suitable for the porogen particles include, for example, organic polymers that are either chemically or thermally degradable. Typically, upon degradation of such porogen particles, the degradation products may be removed from the porous layer with simple solvent washes.

In some embodiments, the porogen may be a liquid such as a solvent (e.g., water, organic solvents, etc.). For example, when the preceramic material described above is used as the matrix material, solvent droplets can act as the porogen. Dispersion of solvent droplets in the preceramic material can be accomplished by vigorous mixing of a mixture containing the two components. The resulting suspension of solvent droplets in matrix material is then cast or otherwise applied to the substrate to form a pre-porous layer. The pre-porous layer can be treated with a crosslinking agent (such as heat, electromagnetic energy, a crosslinking catalyst, etc.) and the solvent droplets removed via heat and/or vacuum, thus forming the porous layer.

In addition to the substrate and porogen or pre-porogen layers, the devices of the invention further comprise various layers within the OLED stack, such as an electroluminescent layer, two electrode layers (i.e., a hole-injection electrode and an electron-injection electrode), an optional dielectric layer, and an optional encapsulation layer. For example, materials for the electrode layers include the transparent electrode materials described above, as well as metals such as Al, Ti, Cr, Mn, Fe, Co, Ni, Cu, Zn, etc., conducting metal oxides such as oxides of Al, Ti, Cr, Mn, Fe, Co, Ni, Cu, or Zn, and other suitable conducting material (such as conducting polymers, etc.). Materials for the dielectric layer and/or encapsulation layer include all of the transparent materials listed previously for the substrate.

The devices of the invention further comprise an electroluminescent layer. Materials that are suitable for electroluminescent layers in the methods of the invention are materials capable of receiving a hole from the hole-injection layer and an electron from the electron-injection layer and emitting electromagnetic radiation (e.g., light) when the injected holes and electrons combine. Accordingly, in certain embodiments, the electroluminescent material may include any of a number of organic or inorganic compounds or mixtures thereof, such as multi-layers of organics or small molecules or the like. For instance, the electroluminescent layer may include a polymeric material or be composed of one or more small molecule materials. However, the material must contain at least one electroluminescent compound, for instance, an organic, inorganic or small molecule electroluminescent compound. In certain embodiments, the electroluminescent compound may include a simple organic molecule or complex polymer or copolymer. For example, a simple organic luminescent molecule may include tris(8-hydroxyquinolinato)-aluminum or perylene.

In certain embodiments, the electroluminescent material includes a polymer or copolymer. The molecular structure of a suitable polymer or copolymer may include a carbon-based or silicon-based backbone. The polymers and copolymers may be linear, branched, crosslinked or any combinations thereof, and may have a wide range of molecular weights from as low as about 5000 to more than 1,000,000. In the case of copolymers, the copolymers may be alternating, block, random, graft copolymers, or combinations thereof. Examples of suitable electroluminescent polymers useful in conjunction with the present invention include, but are not limited to, conjugated polymers such as, polyparaphenylenes, polythiophenes, polyphenylenevinylenes, polythienylvinylenes, polyfluorenes, 1,3,4-oxadiazole-containing polymers, and various derivatives and copolymers thereof.

An exemplary electroluminescent polymer is an arylamine-substituted poly(arylene-vinylene) polymer that has the general structure of formula (II) below:

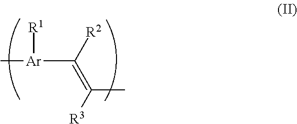

wherein: Ar is arylene, heteroarylene, substituted arylene or substituted heteroarylene containing one to three aromatic rings;

R¹ is the arylamine substituent and is of the formula —Ar¹ —N(R⁴R⁵) wherein Ar¹ is as defined for Ar and R⁴ and R⁵ are independently hydrocarbyl, substituted hydrocarbyl, heteroatom-containing hydrocarbyl, or substituted heteroatom-containing hydrocarbyl; and

R² and R³ are independently selected from the group consisting of hydrido, halo, cyano, hydrocarbyl, substituted hydrocarbyl, heteroatom-containing hydrocarbyl, and substituted heteroatom-containing hydrocarbyl, or R² and R³ may together form a triple bond.

Other moieties may be as follows:

Ar may be a five-membered or six-membered arylene, heteroarylene, substituted arylene or substituted heteroarylene group, or may contain one to three such groups, either fused or linked. Preferably, Ar is comprised of one or two aromatic rings, and is most preferably comprised of a single aromatic ring that is five-membered or six-membered arylene, heteroarylene, substituted arylene or substituted heteroarylene. Ar¹, the arylene linking moiety in the arylamine substituent, is defined in the same way.

The substituents R² and R³ are generally hydrido but may also be halo (particularly chloro or fluoro) or cyano, or substituted or unsubstituted alkyl, alkoxy, alkenyl, alkynyl, aryl and heteroaryl.

R⁴ and R⁵ may the same or different and, as noted, are hydrocarbyl, substituted hydrocarbyl, heteroatom-containing hydrocarbyl, or substituted heteroatom-containing hydrocarbyl. For example, R⁴ and R⁵ may be alkyl, alkoxy-substituted alkyl, polyether-substituted alkyl, nitro-substituted alkyl, halo-substituted alkyl, aryl, alkoxy-substituted aryl, polyether-substituted aryl, nitro-substituted aryl, halo-substituted aryl, heteroaryl, alkoxy-substituted heteroaryl, polyether-substituted heteroaryl, nitro-substituted heteroaryl, halo-substituted heteroaryl, and the like. In certain embodiments the substituents are aryl, e.g., phenyl, alkoxy-substituted phenyl (particularly lower alkoxy-substituted phenyl such as methoxyphenyl), polyether-substituted phenyl (particularly phenyl substituted with a —CH₂(OCH₂ CH₂)ₙ OCH₃ or —(OCH₂ CH₂)₂ OCH₃ group where n is generally 1 to 12, preferably 1 to 6, most preferably 1 to 3), and halo-substituted phenyl (particularly fluorinated or chlorinated phenyl).

Another exemplary electroluminescent polymer material that is described in U.S. Pat. No. 6,414,104, is an arylamine-substituted poly(arylene-vinylene) polymer that contains monomer units having the general structure of formula (III) as follows:

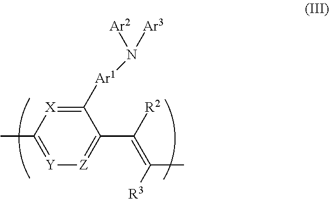

Wherein: X, Y and Z are independently selected from the group consisting of N, CH and CR⁶ wherein R⁶ is halo, cyano, alkyl, substituted alkyl, heteroatom-containing alkyl, aryl, heteroaryl, substituted aryl, or substituted heteroaryl, or wherein two R⁶ moieties on adjacent carbon atoms may be linked to form an additional cyclic group;

Ar¹ is as defined above;

Ar² and Ar³ are independently selected from the group consisting of aryl, heteroaryl, substituted aryl and substituted heteroaryl containing one or two aromatic rings; and

R² and R³ are as defined above.

In formula (I) above, the polymer is a poly(phenylene vinylene) derivative when X, Y and Z are all CH. When at least one of X, Y and Z is N, the aromatic ring will be, for example, substituted or unsubstituted pyridinyl, pyridazinyl, pyrimidinyl, pyrazinyl, 1,2,4-triazinyl, or 1,2,3-triazinyl. For instance, one of X, Y and Z may be CH and the other two may be either CH or CR⁶, wherein R⁶ may be a heteroatom-containing alkyl, for instance, alkoxy, or a polyether substituent —CH₂(OCH₂CH₂)ₙOCH₃ or —(OCH₂CH₂)ₙOCH₃ group where n is may be 1 to 12, for instance, 1 to 6, such as 1 to 3.

The polymer may be a homopolymer or a copolymer with at least one additional type of monomer unit. Preferably, if the polymer is a copolymer, the additional monomer units are also arylene-vinylene monomer units, for example having the structure of Formula (IV):

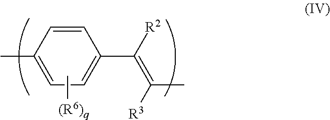

wherein R², R³ and R⁶ are as defined previously and q is an integer in the range of zero to 4 inclusive.

Examples of specific polymers having the structure of formula (I) are poly(2-(4-diphenylamino-phenyl)-1,4-phenylene vinylene and poly(2-(3-diphenylaminophenyl)-1,4-phenylene vinylene.

Examples of specific polymers disclosed in U.S. Pat. No. 6,414,104 are poly(2-(4-diphenylamino-phenyl)-1,4-phenylene vinylene and poly(2-(3-diphenylaminophenyl)-1,4-phenylene vinylene.

Electroluminescent polymers appropriate for use in this invention are also described in U.S. Pat. Nos. 6,723,828, 6,800,722, and 7,098,297, both of which are incorporated by reference herein. In those referenced patents there is disclosed a conjugated polymer containing monomer units having the structure of formula (V):

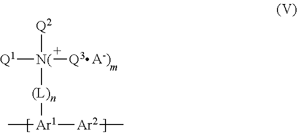

Wherein: Ar¹ and Ar² are independently selected from the group consisting of monocyclic, bicyclic and polycyclic arylene, heteroarylene, substituted arylene and substituted heteroarylene groups;

L is alkylene, alkenylene, substituted alkylene, substituted alkenylene, heteroalkylene, heteroalkenylene, substituted heteroalkylene, substituted heteroalkenylene, arylene, heteroarylene, substituted arylene or substituted heteroarylene;

m is zero or 1;

n is zero or 1;

Q¹ and Q² are independently selected from the group consisting of H, aryl, heteroaryl, substituted aryl, substituted heteroaryl, alkyl, and substituted alkyl, and Q³ is selected from the group consisting of alkyl and substituted alkyl, with the proviso that when m is 1, Q¹ and Q² are other than H; and

A⁻ is a negatively charged counterion.

The electroluminescent material may also include blends of polymers within formula (IV) with other polymers, as well as a variety of copolymers.

### Devices, Preparation, and Characteristics

The shape and size of the porogen particles may be varied in order to vary the size and shape of the pores in the porous layer. Typical porogen particles are spherical, but other shapes (e.g., rods, cubes, etc.) may be used as well. In preferred embodiments, porogen particles are used that have an average diameter (or, in the case of non-spherical particles, have a longest dimension) in the range of 10 nm to about 1000 nm, or about 10 nm to about 500 nm, or about 10 nm to about 300 nm, or about 10 nm to about 100 nm, or about 30 nm to about 500 nm, or about 50 nm to about 500 nm, or about 80 nm to about 500 nm, or about 100 nm to about 500 nm. In some preferred embodiments, porogen particles are used having an average diameter that is greater than about 10 nm, or greater than about 30 nm, or greater than about 50 nm, or greater than about 80 nm, or greater than about 100 nm, or greater than about 150 nm, or greater than about 200 nm, or greater than about 300 nm, or greater than about 500 nm. In some embodiments, porogen particles are used having an average diameter that is less than about 500 nm, or less than about 300 nm, or less than about 200 nm, or less than about 150 nm, or less than about 100 nm, or less than about 80 nm, or less than about 50 nm, or less than about 30 nm.

In the porogen removal step, the pre-porous layer is contacted with a porogen removal agent (such as an acid in the case of a metal porogen, as described above) for a time sufficient to cause removal of at least a portion of the porogen material present in the pre-porous layer. Porogen particles that are exposed to the porogen removal agent are degraded or otherwise removed from the pre-porous layer. For example, where the porogen is a metal, and the porogen removal agent is an aqueous acid, contact of the metal with the acid causes the metal to react, forming a charged metal species that dissolves in the aqueous solution. In this way the porogen is removed from the pre-porous layer, leaving pores filed with an aqueous solution. Removal of the aqueous solution and subsequent washing and/or drying leaves pores in the porous layer that are exposed to the environment.

It should be noted that, as used herein, the term “pores” includes spaces within a material that may be filled with any material other than the surrounding matrix material. Pores may be filled with an inert gas, air, a liquid, or a solid such as the porogen. Thus, the pre-porous layer comprises pores that are filled with a porogen material. The porous layer comprises pores that are filled with one or more materials selected from the porogen material, gases, and liquids.

In preferred embodiments, the pre-porous layer comprises porogen particles arranged in a monolayer. In some embodiments, however, the porogen particles may be present in more than a monolayer, such that there are multiple layers of porogen particles within the pre-porous layer. It is preferable to mix the porogen particles with the matrix material such that minimal aggregation of porogen particles occurs. The density of particles, as measured by particles/area or particles/volume may be varied with the concentration of particles in the composition used to produce the pre-porous layer as well as the thickness of the pre-porous layer. The density of porogen particles, and therefore the density of pores in the porous layer may be varied as appropriate to obtain the desired optical properties of the porous layer and the OLED device. In some embodiments, a tight packed monolayer of porogen particles (i.e., wherein adjacent particles touch) is prepared, and in other embodiments, a dispersed monolayer of porogen particles (i.e., wherein adjacent particles do not touch) is prepared. Tight packed monolayers of porogen particles give rise to porous layers having an open cell structure, whereas dispersed monolayer of porogen particles give rise to closed cell porous layers. Furthermore, for any given porous layer, the density of pores may be substantially homogeneous over the entire layer or may be location dependent. Examples of location dependent porous layers include those having radially increasing or radially decreasing pore density (i.e., pore density increases or decreases with distance from a central point), and such heterogeneous distributions may be employed to obtain desirable optical characteristics of the OLED device.

In some embodiments, the thickness of the pre-porous layer will be in the range of about 10 nm to about 1000 nm, or about 10 nm to about 500 nm, or about 10 nm to about 300 nm, or about 10 nm to about 100 nm, or about 30 nm to about 500 nm, or about 50 nm to about 500 nm, or about 80 nm to about 500 nm, or about 100 nm to about 500 nm. In preferred embodiments, the thickness of the pre-porous layer will be between one and two times the diameter of the porogen particles used in the pre-porous layer material. In preferred embodiments, the thickness of the pre-porous layer will be about 100%, or about 150%, or about 200%, or about 250% of the diameter of the porogen particles used in the pre-porous layer material.

The percentage of porogen particles at or near the external surface of the pre-porous layer will depend, in part, upon the thickness of the pre-porous layer relative to the diameter of the porogen particles. For example, if the pre-porous layer is several times thicker than the diameter of the porogen particles, a relatively smaller percentage of porogen particles will be at or near the external surface, whereas if the pre-porous layer is the same (or nearly the same) thickness as the diameter of the porogen particles, most or all of the particles will be at the external surface.

Generally, although not necessarily, porogen particles at or near the external surface of the pre-porous layer will be better exposed to the porogen removal agent during the porogen removal step, and are more likely to be removed in whole or in part during the porogen removal step. For example, when aqueous acid is used as the porogen removal agent, only porogen particles that are exposed to the aqueous solution will react with the acid. Substantially all of the porogen particles that are at or near the surface of the pre-porous layer will be exposed to, and react with, the acid. Porogen particles that are completely encapsulated within the matrix material and are not at or near the external surface will generally not be exposed to the aqueous acid under the conditions used for the porogen removal step. Accordingly, after the porogen removal step, some porogen particles may remain in whole or in part in the porous layer. Such particles will likely not affect the electrical properties of the device, although it will be appreciated that the optical properties of the porogen layer may be altered by including more or less of such residual porogen particles.

It will be appreciated that, when the porogen removal step does not employ a porogen removal agent (e.g., when heat or vacuum is used in the porogen removal step), the location of the porogen particles within the pre-porous layer will have less influence in the amount of porogen material that is removed in the porogen removal step. In some embodiments, substantially all of the porogen material is removed (including material that is completely encapsulated within the matrix material, and not at or near the external surface) by application of heat or vacuum.

In some embodiments, the process of preparing a porous layer includes depositing a pre-porous layer and subsequently etching (or otherwise removing) material from the pre-porous layer (prior to exposing the pre-porous layer to a porogen removal agent). This etching step typically increases the amount of porogen material that is exposed at the surface of the pre-porous layer, particularly when an etchant is used that selectively removes the matrix material and leaves the porogen material intact.

Depending on the thickness of the pre-porous layer and the diameter of the porogen particles, the microcavities created by removal of porogen particles will extend partially into the porous layer. For example, the microcavities may extend to a depth of 0.001%, or 0.01%, or 0.1%, or 1%, or 5%, or 10%, or 15%, or 25%, or 35%, or 50%, or 65%, or 75%, or 90% of the thickness of the porous layer. Also for example, the microcavities may extend to a depth between 0.001% and 0.01%, or between 0.01% and 0.1%, or between 1% and 10%, or between 10% and 25%, or between 15% and 35%, or between 25% and 50%, or between 25 and 75% of the thickness of the porous layer. It will be appreciated that these percentages represent average depths of extension into the porous layer, as depths for individual microcavities will vary. In some embodiments, the microcavities may extend completely through the porous layer.

In some embodiments, the process of preparing a porous layer comprising microcavities further comprises a final etching step after the porogen removal step. This final etching step etches (or otherwise removes) material from the porous layer. Typically, the final etching step modifies the shape of the microcavities (such as, for example, enlarging the microcavities or enlarging the openings of the microcavities that are exposed to the environment). Such modifications may be used where it is desired to change the optical properties of the porous layer, and in some embodiments enlargement of the microcavities increases light extraction efficiency for the device.

Deposition of the pre-porous or porous layer can be accomplished by any appropriate method. For example, methods include chemical solution deposition methods, such as sol-gel processing, dip coating, spin coating, spray coating, and the like. In one example embodiment, a mixture comprising a matrix material (a cross-linkable pre-ceramic material) and a porogen (metal particles) in a solvent is prepared, mixed well, and then spun or cast onto the substrate of an OLED device. The pre-porous layer thus prepared is treated with acid, which dissolves the porogen particles exposed at the surface of the pre-porous layer. The porous layer thus prepared is treated with heat to crosslink the pre-ceramic material. Alternatively, the pre-porous layer may be treated with heat to first crosslink the pre-ceramic material, and subsequently treated with acid to remove the porogen.

In some cases, it is desirable to coat the walls of the microcavities with a layer of a reflective material such as a metal. Such a coating can be applied by the normal means such as thermal evaporation, sputtering, or chemical vapor deposition. In some embodiments, the deposition is performed at controlled angles such that only certain faces of the microcavity walls are coated. Coatings of reflective materials further help to redirect photons incident on the microcavities such that they are emitted into the environment (rather than captured within the porous layer).

Thus, in some embodiments, the invention comprises applying a pre-porous layer to the outermost transparent layer of an OLED. The outermost transparent layer may be the substrate, a transparent electrode layer, or an encapsulation layer. The pre-porous layer comprises a matrix material and porogen. After application, the porogen is removed from the pre-porous layer in order to form a porous layer, and the matrix material is crosslinked. Removal of the porogen and crosslinking of the matrix material may be accomplished in any order as appropriate for the compounds involved. In some embodiments, the porous layer is a ceramic material. In other embodiments, the porous layer is a polymer material.

In some embodiments, a pre-porous layer is applied directly to a substrate that supports an OLED. In such embodiments, formation of the porous layer by removal of the porogen occurs while the pre-porous layer is in contact with the substrate that supports the OLED. Such embodiments (referred to herein as “direct preparation”) involve the following steps: providing an OLED comprising a substrate layer, first and second electrode layers, and an electroluminescent layer; applying to the substrate layer a solution comprising a matrix material and a porogen to form a pre-porous layer; and removing the porogen to form a porous layer. Such embodiments may further include, wherein applicable, the step of curing (e.g., crosslinking) the matrix material.

In other embodiments, a pre-porous layer is applied to an auxiliary substrate, the porous layer is formed by removal of the porogen, and then the auxiliary substrate is applied to a substrate that supports an OLED. Such embodiments (referred to herein as “indirect preparation”) involve the following steps: providing an auxiliary substrate layer; applying to a first side of the auxiliary substrate layer a solution comprising a matrix material and a porogen to form a pre-porous layer; removing the porogen to form a porous layer attached to the first side of the auxiliary substrate; providing an OLED comprising a primary substrate layer, first and second electrode layers, and an electroluminescent layer; applying the auxiliary substrate to the primary substrate layer such that a second side of the auxiliary layer contacts the primary substrate layer. The indirect preparation method is suitable when the OLED device would be sensitive to the conditions necessary for removal of the porogen. Typically, an auxiliary substrate is a free-standing layer that is made of the same material as the primary substrate layer supporting an OLED. Alternatively, the auxiliary substrate may be made of any material that has the same (or nearly the same) index of refraction as the primary substrate layer, or the auxiliary substrate may be made of any material that has a different index of refraction as the primary substrate layer. In preferred embodiments, the amount of reflection is minimized as photons traverse the interface between the primary substrate and the auxiliary substrate.

In some embodiments, as described previously, it is desirable to have a non-uniform porous layer (i.e., a porous layer with a heterogeneous distribution of pores) in that the porosity of the porous layer varies at different positions over the OLED substrate. This may be desired where the output properties of the OLED is non-uniform, or specific optical properties are desired.

### Figures

With reference to FIG. 1, one embodiment of the invention, device 100, is illustrated graphically. OLED stack 20 is in contact with substrate 10. Light emitted from OLED stack 20 is directed such that it travels through substrate 10, as shown for light rays 1, 2, and 3. Substrate 10 has outermost surface 11 (“outermost” indicates that it is furthest away from OLED stack 20) that forms an interface with the environment. Surface 11 contains surface roughening features in the form of a plurality of voids 12 (two specific voids are identified as 12a and 12b). The plurality of voids 12 increases the surface area of the interface between substrate 10 and the environment.

In device 100, light rays 1, 2, and 3 are emitted from OLED 20 into substrate 10. Light ray 1 passes through surface 11 because it encounters surface 11 at a sufficiently low angle of incidence. Light rays 2 and 3 are emitted from OLED 20 such that they encounter surfaces within voids 12a and 12b, respectively. Due to these encounters, light rays 2 and 3 are redirected (either by reflection or refraction) to exit substrate 10. In the absence of a void 12, light ray 2 would encounter surface 11 with a large angle of incidence and reflect back into substrate 10 (as shown by the dashed portion of light ray 2). Similarly, light ray 3 would reflect back into substrate 10 if it were to encounter surface 11 as shown by the dashed portion of light ray 3. Because of the presence of voids 12a and 12b, therefore, both light ray 2 and light ray 3 are able to exit device 100. Accordingly, the presence of voids 12 and the increased surface area of the interface between substrate 10 and the environment increases the EQE of device 100 relative to a similar device having no voids 12.

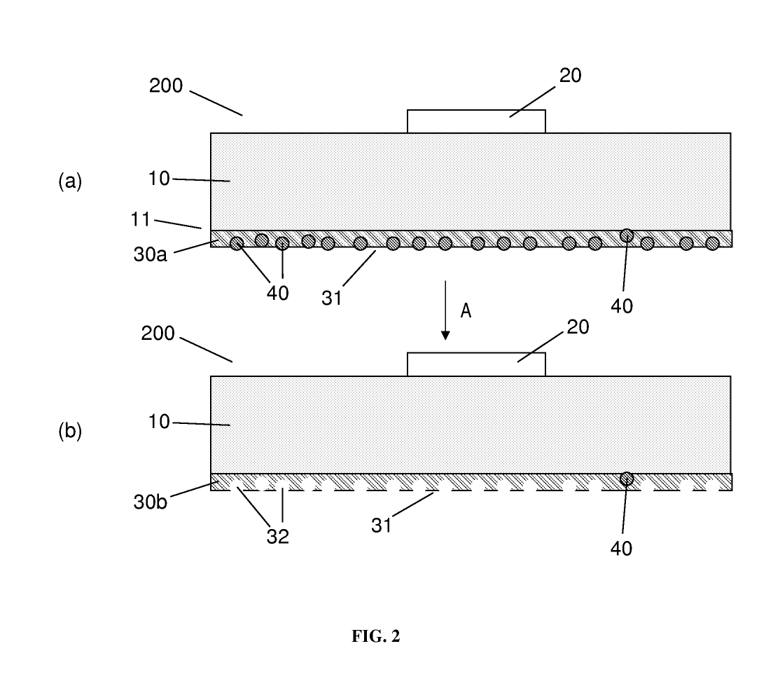

FIG. 2 is a graphic that represents the formation of device 200 according to an embodiment of the invention. In device 200, OLED stack 20 is in contact with substrate 10. Substrate 10 has surface 11 that is located distally from OLED 20. In panel (a), surface 11 is in conformal contact with pre-porous layer 30a. Pre-porous layer 30a has outermost surface 31, which forms an interface between device 200 and the environment. Pre-porous layer 30a comprises a matrix material embedded with a plurality of porogen particles 40. A substantial portion of porogen particles 40 protrude through surface 31 and are exposed to the environment. Through process step A, porogen particles 40 are removed from device 200. Thus, in panel (b), surface 11 of substrate 10 is in conformal contact with porous layer 30b, which forms an interface between device 200 and the environment. Porous layer 30b comprises a plurality of pores 32. For each pore 32, outermost surface 31 of porous layer 30b extends into the interior of porous layer 30b. In other words, outermost surface 31 is not a flat/smooth surface due to the presence of pores 32. Porous layer 30b may contain residual porogen particles 40 that are not exposed to the environment (i.e., do not protrude through surface 31) and are therefore not removed during process step A.

The methods and devices disclosed herein have one or more advantages over those previously known. Such advantages include, for example, greater EQE, lower power consumption (for a given output), and simplified fabrication (compared, for example, with devices that use microlenses). Although the methods and materials of the invention are compatible with lithographic fabrication processes, lithography is not required to achieve the high-efficiency output surfaces of the invention.

All patents, patent applications, and publications mentioned herein are hereby incorporated by reference in their entireties. However, where a patent, patent application, or publication containing express definitions is incorporated by reference, those express definitions should be understood to apply to the incorporated patent, patent application, or publication in which they are found, and not to the remainder of the text of this application, in particular the claims of this application.

It is to be understood that while the invention has been described in conjunction with the preferred specific embodiments thereof, that the foregoing description as well as the examples that follow, are intended to illustrate and not limit the scope of the invention. It will be understood by those skilled in the art that various changes may be made and equivalents may be substituted without departing from the scope of the invention, and further that other aspects, advantages and modifications will be apparent to those skilled in the art to which the invention pertains.

### EXAMPLES

### Example 1

An OLED was encapsulated with a cover glass and the routine current-voltage-brightness (JVB) test was performed. The front surface of the device was then sand blasted and the JVB test was performed again. The recorded external quantum efficiency before and after sand blasting were compared.

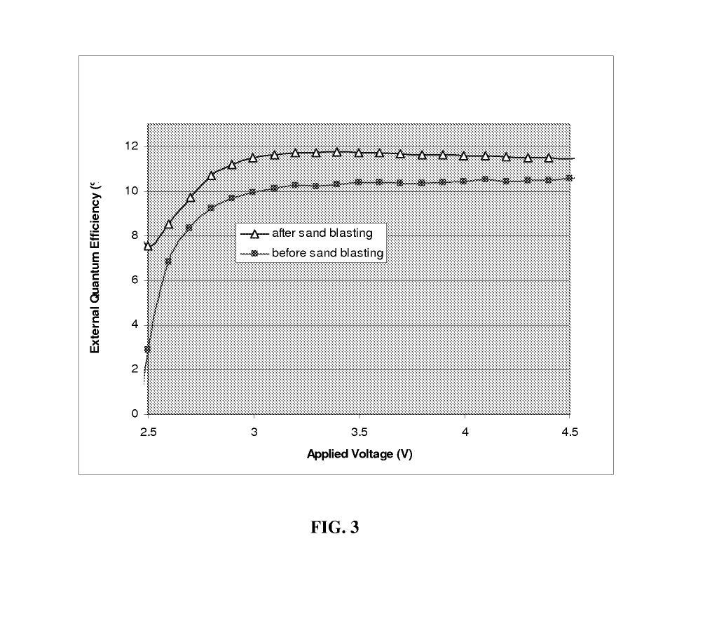

A sample data set is shown in FIG. 3 (square data points represent the device before sand blasting; triangular data points represent the device after sand blasting). Depending on the location of the OLED pixel, the observable EQE enhancement varies from 10% -20%, due to the non-uniformity of sand blasting.

### Example 2

A metal power (such as Aluminum powder) or metal oxide powder (such as aluminum oxide or titanium oxide) is dispersed into a solution of the preceramic polymer (PHMSOH); this dispersion is then coated on top of the substrate; the metal (or metal oxide) particles are removed by soaking the substrate into an acid (such as hydrocholoric acid, nitric acid, sulfuric acid, or their mixtures) to form a porous layer. The PHMS-OH is final cured by heat.

Example: to a PHMS-OH solution containing ca 5 wt % solid was added equal amount of TiO2 powder. The mixture is shaken vigorously and then spin-coated on to a glass substrate. Immediately after the spin-coating, the substrate is soaked into a 1:1 mixture of hydrochloric acid and nitric acid for 5-10 min. The substrate is then removed from the acid and rinsed with deionized water, blow-dry, and baked on a hotplate at 160° C. for approximately 1 hr. After applying this film (i.e., applying the combination of the film on the glass substrate) onto a regular OLED or a COLED-B device having a glass substrate, a ˜30% enhancement in external quantum efficiency (EQE) is observable.

### Example 3

An organic marcro molecular or polymer is dispersed (or dissolved) into a solution of the preceramic polymer (PHMS-OH); then coated on the substrate surface. The PHMS-OH is then thermally cured; then the organic component (the organic polymer molecules) is removed by oxidation to generate the required porous PHMS-OH film.

### Example 4

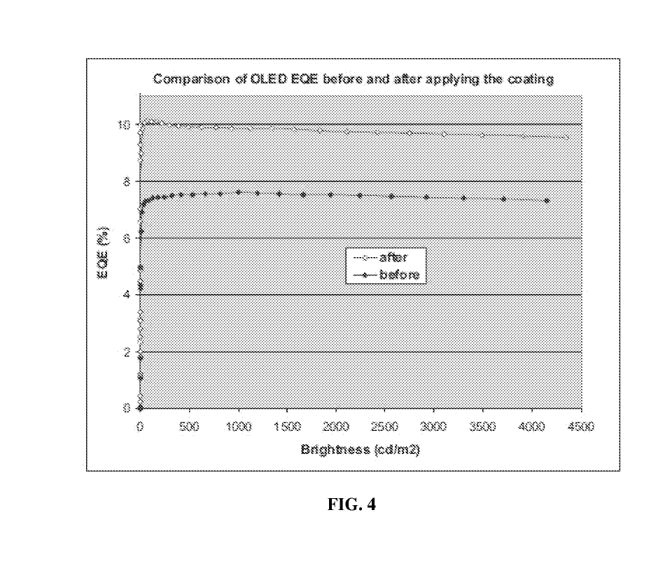

A microscope glass slide was cleaned using detergent and then by air plasma for a few minutes. A suspension of TiO₂ nano-particles dispersed in a 5 wt % of preceramic polymer PHMS-OH solution (solvent: isopropyl alcohol) was spin-coated onto the substrate surface. Immediately after the spin-coating, the substrate is soaked into a 1:1 mixture of hydrochloric acid and nitric acid for approximately 5 min; the substrate is then removed from the acid bath and subsequently rinsed with deionized water, dried using a nitrogen gun, and finally baked on a hotplate at 160° C. for approximately 1.5 hour. When this glass slide (with the coating on the top surface) was glued onto the emissive side of an OLED device, the device external quantum efficiency (EQE) is increased by approximately 30% (See EQE comparison in the plot shown in FIG. 4).

What is claimed is:

1. A light emitting diode (LED) device comprising:
a transparent substrate layer having first and second sides;
a first electrode layer contacting the first side of the substrate layer;
an electroluminescent layer contacting the first electrode layer;
a second electrode layer contacting the electroluminescent layer; and
a porous layer contacting the second side of the substrate.

2. The LED of claim 1, wherein the porous layer comprises a matrix material and a plurality of pores.

3. The LED of claim 2, wherein the porous layer is prepared from a pre-porous layer that comprises a plurality of porogen particles.

4. The LED of claim 3, wherein the porogen material comprises a metal or metal oxide.

5. The LED of claim 2, wherein the matrix material is a cross-linkable preceramic or polymeric material.

6. The LED of claim 2, wherein the matrix material is a cross-linked ceramic or polymeric material.

7. The LED of claim 1, wherein the LED further comprises:
a dielectric layer interposed between at least a portion of the first electrode layer and at least a portion of the electroluminescent layer;
a plurality of cavities extending at least through the dielectric layer, wherein the cavities comprise electroluminescent material from the electroluminescent layer, and wherein the electroluminescent material contacts a surface of the dielectric layer and a surface of the first electrode layer.

8. A light emitting diode (LED) device comprising:
a substrate layer;
a first electrode layer contacting the substrate layer;
an electroluminescent layer contacting the first electrode layer;
a second electrode layer, wherein a first side of the second electrode layer contacts the electroluminescent layer, and wherein the second electrode layer is transparent; and
a porous layer contacting a second side of the second electrode layer.

9. A method for increasing the efficiency of an LED comprising:
applying to the LED a transparent pre-porous layer comprising a cross-linkable matrix material and a porogen; and
forming a transparent porous layer by removing all or a portion of the porogen and cross-linking the matrix material.

10. The method of claim 9, wherein the LED is an organic LED (OLED) comprising:
a substrate; a first electrode layer contacting the substrate; an electroluminescent layer contacting the electrode; a second electrode layer contacting the electroluminescent layer; and an optional encapsulation layer contacting the second electrode layer,

11. The method of claim 10, wherein the substrate is transparent, and wherein the OLED stack is configured to generate photons in the electroluminescent layer and emit the photons through a surface of the substrate.

12. The method of claim 10, wherein the second electrode is transparent, and wherein the OLED stack is configured to generate photons in the electroluminescent layer and emit the photons through a surface of the second electrode layer or through a surface of the optional encapsulation layer.

13. The method of claim 10, wherein the transparent pre-porous layer is applied to a surface of the substrate.

14. The method of claim 10, wherein the transparent pre-porous layer is applied to a surface of the second electrode layer or to a surface of the optional encapsulation layer.

15. The method of claim 9, wherein the cross-linkable matrix material is a preceramic material or a polymeric material.

16. The method of claim 15, wherein the cross-linking cures the cross-linkable material to form a ceramic material or a cross-linked polymeric material.

17. The method of claim 9, wherein the porogen comprises a metal or metal oxide powder, and wherein the porogen is removed by contacting the pre-porous layer with an etching solution.

18. The method of claim 9, wherein removing all or a portion of the porogen occurs prior to the cross-linking.

19. The method of claim 9, wherein removing all or a portion of the porogen occurs simultaneously with the cross-linking.

20. A method for increasing the efficiency of an LED having an outermost layer, the method comprising:
contacting the transparent outermost layer with a porous transparent layer such that the porous transparent layer affixes to the outermost layer.
